(19) United States
(12) Patent Application Publication
(10) Pub. No.: US 2024/0240321 A1
(43) Pub. Date: Jul. 18, 2024

(54) SUBSTRATE PROCESSING APPARATUS AND SUBSTRATE PROCESSING METHOD

(71) Applicant: JUSUNG ENGINEERING CO., LTD., Gwangju-si, Gyeonggi-do (KR)

(72) Inventors: Da Un JUNG, Seongnam-si, Gyeonggi-do (KR); In Woo BACK, Yongin-si Gyeonggi-do (KR); Jin An JUNG, Yongin-si, Gyeonggi-do (KR)

(21) Appl. No.: 18/559,485

(22) PCT Filed: Apr. 28, 2022
(86) PCT No.: PCT/KR2022/006093

§ 371 Date: Nov. 7, 2023

(30) Foreign Application Priority Data
May 7, 2021 (KR) 10-2021-0059361

(51) Int. Cl. C23C 16/46; C23C 16/458; C23C 16/52

(52) U.S. Cl. CPC C23C 16/46; C23C 16/4584; C23C 16/52

(57) ABSTRACT

Disclosed are a substrate processing apparatus and method, wherein the number of second measurement units disposed above a substrate in order to measure the temperature of the substrate is less than the number of first measurement units disposed under a heater in order to measure the temperature of the heater, the temperature of the substrate is calculated in real time during a process, and the temperature of the heater is controlled based thereon, whereby it is possible to maintain uniform temperature of the entirety of the substrate. As a result, it is possible to deposit a film having a uniform thickness, thereby improving completeness of a deposition process.

### BACKGROUND

### Technical Field

The present inventive concept relates to a substrate processing apparatus and method capable of measuring the temperature of a substrate in a chamber in real time.

### Discussion of the Related Art

In general, a semiconductor device, a display device, or a thin film solar cell is manufactured through a thin film deposition process of depositing a thin film made of a specific material on a substrate, a photolithography process of exposing or concealing a selected area of the thin film using a photosensitive material, and an etching process of removing the thin film in the selected area and performing patterning. Thereamong, the thin film deposition process and the etching process are performed by a substrate processing apparatus optimized in a vacuum state.

In the substrate processing apparatus optimized in the vacuum state, a substrate is heated using a heating means, and process gas is supplied into a reaction space of a chamber in order to perform the thin film deposition process and the etching process. In a substrate processing process, the temperature of the substrate must be accurately measured, since the temperature of the substrate affects the quality of a product.

The temperature of the entire area of the substrate or the temperatures of a plurality of areas of the substrate are measured to calculate the distribution in temperate of the substrate, whereby process uniformity is secured.

In order to measure the temperature of the entire area of the substrate or the temperatures of the plurality of areas of the substrate, a plurality of temperature measurement devices must be disposed at positions corresponding to the areas to be measured. A space necessary to install the plurality of temperature measurement devices must be provided above the substrate, and therefore there is a need for research on a substrate processing apparatus and method capable of improving space utilization.

### SUMMARY OF THE INVENTIVE CONCEPT

Accordingly, the present inventive concept is directed to a substrate processing apparatus and method that substantially obviate one or more problems due to limitations and disadvantages of the related art.

It is an object of the present inventive concept to provide a substrate processing apparatus and method capable of measuring the temperature of a substrate in a chamber in real time.

It is another object of the present inventive concept to provide a substrate processing apparatus and method capable of maintaining uniform temperature of a substrate in a chamber.

It is a further object of the present inventive concept to provide a substrate processing apparatus and method capable of improving completeness of a deposition process.

Additional advantages, objects, and features of the inventive concept will be set forth in part in the description which follows and in part will become apparent to those having ordinary skill in the art upon examination of the following or may be learned from practice of the inventive concept. The objectives and other advantages of the inventive concept may be realized and attained by the structure particularly pointed out in the written description and claims hereof as well as the appended drawings.

To achieve these objects and other advantages and in accordance with the purpose of the inventive concept, as embodied and broadly described herein, a substrate processing apparatus includes a chamber, a susceptor configured to support a substrate in the chamber, a heater disposed under the susceptor, one or more first measurement units configured to measure the temperature of the heater, and one or more second measurement units configured to measure the temperature of the substrate, wherein the first measurement units and the second measurement units are different from each other in number. The number of the second measurement units may be less than the number of the first measurement units.

In the substrate processing apparatus according to the present inventive concept, the second measurement units may be spaced apart from each other by a predetermined distance.

The substrate processing apparatus according to the present inventive concept may further include a calculator configured to calculate the temperature of a second area of the substrate using measured values of a first area measured by the first measurement unit and the second measurement unit and measured values of a third area measured by the first measurement unit and the second measurement unit, the second area being located between the first area and the third area.

In the substrate processing apparatus according to the present inventive concept, the calculator may calculate the temperature of the second area of the substrate using at least one of the difference between the measured values of the first area measured by the first measurement unit and the second measurement unit and the measured values of the third area measured by the first measurement unit and the second measurement unit and the average thereof.

In a substrate processing apparatus according to another embodiment of the present inventive concept, the calculator may use a measured value of the second area measured by the first measurement unit.

In a substrate processing apparatus according to a further embodiment of the present inventive concept, the susceptor may be rotatable while supporting a plurality of substrates, and the second measurement units may be disposed above the plurality of substrates, respectively. At this time, the controller may control the operation of the second measurement units using the rotation speed of the susceptor.

In another aspect, a substrate processing method includes a first step of measuring heater temperature and substrate temperature at a first area, a second step of measuring heater temperature and substrate temperature at a third area, and a third step of calculating substrate temperature at a second area using the measured values of the first area and the second area, the second area being located between the first area and the third area.

In a further aspect, a substrate processing method includes a first step of measuring and storing heater temperature, a second step of measuring and storing substrate temperature, and a third step of calculating substrate temperature at a second area using a measured heater temperature value and a measured substrate temperature value at a first area and a measured heater temperature value and a measured substrate temperature value at a third area, the second area being located between the first area and the third area.

In the substrate processing method according to the present inventive concept, the substrate temperature at the second area may be calculated using at least one of the difference between the heater temperature and the substrate temperature at the first area and the third area and the average thereof.

In a further aspect, a substrate processing method includes a first step of measuring and storing heater temperature, a second step of measuring and storing substrate temperature, and a third step of calculating substrate temperature at a second area using a measured heater temperature value and a measured substrate temperature value at a first area and a measured heater temperature value and a measured substrate temperature value at a third area, the second area being located between the first area and the third area.

[symbol]

[symbol]

In the substrate processing method according to the present inventive concept, a measured heater temperature value at the second area may be further used.

It is to be understood that both the foregoing general description and the following detailed description of the present inventive concept are exemplary and explanatory and are intended to provide further explanation of the inventive concept as claimed.

### BRIEF DESCRIPTION OF THE DRAWINGS

The accompanying drawings, which are included to provide a further understanding of the inventive concept and are incorporated in and constitute a part of this application, illustrate embodiment (s) of the inventive concept and together with the description serve to explain the principle of the inventive concept. In the drawings:

FIG. 1 is a view showing some constructions of a substrate processing apparatus according to an embodiment of the present inventive concept based on a chamber;

FIG. 2 is a block diagram schematically showing the construction of the substrate processing apparatus according to the present inventive concept;

FIG. 3 is an illustrative view showing the area of a substrate measured by a second measurement unit in the substrate processing apparatus according to the construction of FIG. 1;

FIG. 4 is a view showing some constructions of a substrate processing apparatus according to another embodiment of the present inventive concept based on a chamber;

FIG. 5 is an illustrative view showing the area of a substrate measured by a second measurement unit in the substrate processing apparatus according to the construction of FIG. 4;

FIG. 6 is an illustrative view describing disposition and operation of a first measurement unit and the second measurement unit in the substrate processing apparatus according to the present inventive concept;

FIG. 7 is a flowchart showing steps of a substrate processing method according to an embodiment of the present inventive concept; and

FIG. 8 is a flowchart showing steps of a substrate processing method according to another embodiment of the present inventive concept.

### DETAILED DESCRIPTION OF THE INVENTIVE CONCEPT

Specific structural or functional descriptions of the embodiments of the present inventive concept disclosed in this specification are given only for illustrating embodiments of the present inventive concept. Embodiments of the present inventive concept may be realized in various forms, and should not be interpreted to be limited to the embodiments of the present inventive concept disclosed in this specification.

Since the embodiments of the present inventive concept may be variously modified and may have various forms, specific embodiments will be shown in the drawings and will be described in detail in this specification. However, the embodiments according to the concept of the present inventive concept are not limited to such specific embodiments, and it should be understood that the present inventive concept includes all alterations, equivalents, and substitutes that fall within the idea and technical scope of the present inventive concept.

It will be understood that, although the terms “first”, “second”, etc. may be used herein to describe various elements, corresponding elements should not be understood to be limited by these terms, which are used only to distinguish one element from another. For example, within the scope defined by the present inventive concept, a first element may be referred to as a second element, and similarly, a second element may be referred to as a first element.

It will be understood that, when a component is referred to as being “connected to” or “coupled to” another component, it may be directly connected to or coupled to the other component, or intervening components may be present. In contrast, when a component is referred to as being “directly connected to” or “directly coupled to” another component, there are no intervening components present. Other terms that describe the relationship between components, such as “between” and “directly between” or “adjacent to” and “directly adjacent to”, must be interpreted in the same manner.

The terms used in this specification are provided only to explain specific embodiments, but are not intended to restrict the present inventive concept. A singular representation may include a plural representation unless it represents a definitely different meaning from the context. It will be further understood that the terms “comprises”, “has” and the like, when used in this specification, specify the presence of stated features, numbers, steps, operations, elements, components or combinations thereof, but do not preclude the presence or addition of one or more other features, numbers, steps, operations, elements, components, or combinations thereof.

Unless otherwise defined, all terms, including technical and scientific terms, used in this specification have the same meanings as those commonly understood by a person having ordinary skill in the art to which the present inventive concept pertains. It will be further understood that terms, such as those defined in commonly used dictionaries, should be interpreted as having meanings consistent with their meanings in the context of the relevant art and the present disclosure, and are not to be interpreted in an idealized or overly formal sense unless expressly so defined herein.

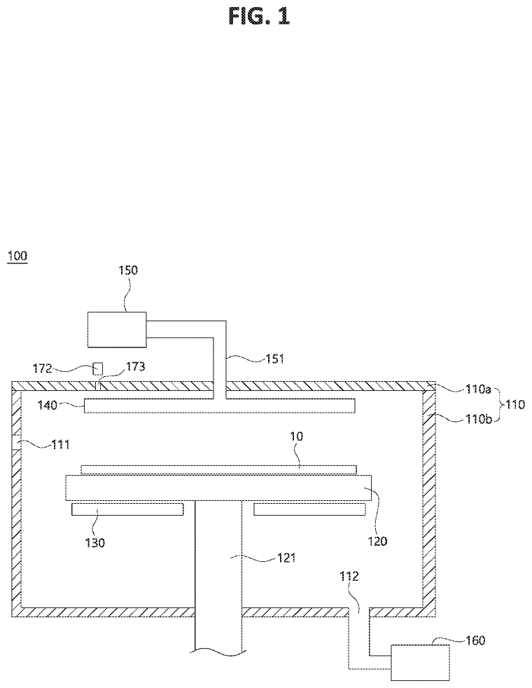

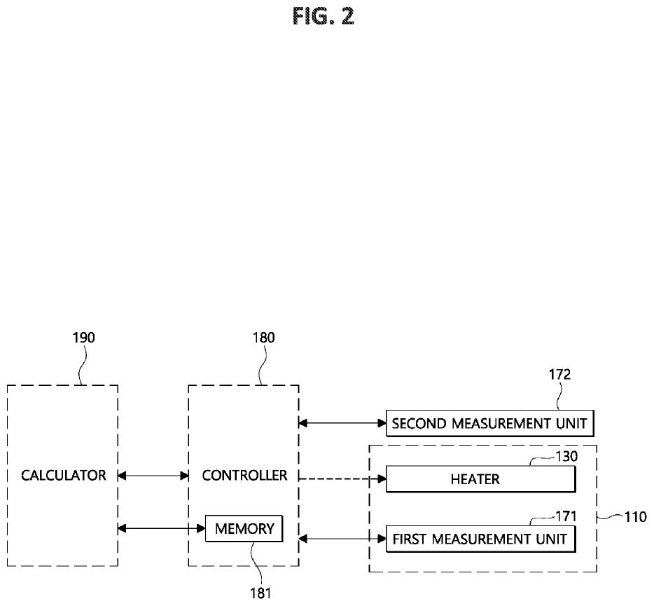

Hereinafter, a substrate processing apparatus and method according to the present inventive concept will be described with reference to the accompanying drawings. FIG. 1 is a view showing some constructions of a substrate processing apparatus according to an embodiment of the present inventive concept based on a chamber, and FIG. 2 is a block diagram schematically showing the construction of the substrate processing apparatus according to the present inventive concept.

The substrate processing apparatus 100 according to the embodiment of the present inventive concept may include a chamber 110 having a reaction space, a susceptor 120 provided in the chamber 110 to support a substrate 10, a heater 130 disposed under the susceptor 120 to heat the susceptor 120, a gas injector 140 provided in the chamber 110 so as to be opposite the susceptor 120 to inject process gas, a gas supply unit 150 provided outside the chamber 110 to supply process gas to the gas injector 140, and an exhaust unit 160 configured to exhaust the chamber 110.

The chamber 110 includes a chamber body 110b and a lead 110a disposed at an upper end of the chamber body 110b. The chamber body 110b and the lead 110a are coupled to each other to define the reaction space in the chamber 110. The chamber 110 may be formed in the shape of a barrel having formed therein a space for substrate deposition. The chamber 110 may be formed in various shapes depending on the shape of the substrate 10. Here, a silicon substrate for semiconductor manufacture or a glass substrate for flat panel display manufacture may be used as the substrate 10. That is, when the substrate 10 is circular, like a silicon substrate, the chamber 110 may be formed in a cylindrical shape having a circular cross section. When the substrate 10 is quadrangular, like a glass substrate, the chamber 110 may be formed in a hexahedral shape having a quadrangular cross section.

The susceptor 120 and the gas injector 140 may be disposed in the chamber 110 so as to be opposite each other. For example, the susceptor 120 may be disposed at a lower side of the chamber 110, and the gas injector 140 may be disposed at an upper side of the chamber 110. In addition, a substrate gate 111, through which the substrate 10 is introduced and removed, may be provided at one side of the chamber 110. The chamber 110 may be provided with a gas inlet 151, which is connected to the gas supply unit 150 that supplies process gas into the chamber 110.

In addition, an exhaust unit 160 may be connected to an exhaust port 112 provided in a lower part of the chamber 110 in order to adjust pressure in the chamber 110 or to exhaust process gas and foreign matter in the chamber 110.

For example, the substrate gate 111 may be provided in one side surface of the chamber 110 so as to have a sufficient size for the substrate 10 to be introduced and removed, the gas inlet 151 may be formed through an upper wall of the chamber 110, and the exhaust port 112 may be formed through a lower wall of the chamber 110, which is lower than the susceptor 120.

The susceptor 120 is provided in the chamber 110, and at least one substrate 10 introduced into the chamber 110 is seated on the susceptor. In order for the substrate 10 to be seated on and supported by the susceptor 120, the susceptor 120 may be provided with, for example, an electrostatic chuck configured to maintain the state in which the substrate 10 is suctioned by electrostatic force, or may support the substrate 10 by vacuum suction or using mechanical force. In addition, the susceptor 120 may be formed in a planar shape corresponding to the shape of the substrate 10, such as a circular shape or a quadrangular shape, and may be manufactured so as to have a size greater than the size of the substrate 10.

A lift 121 configured to move the susceptor 120 upwards and downwards may be provided under the susceptor 120. The lift 121 is configured to support at least one area, for example a central part, of the susceptor 120. When the substrate 10 is seated on the susceptor 120, the lift 121 moves the susceptor 120 so as to be adjacent to the gas injector 140.

In addition, the heater 130 may be mounted under or in the susceptor 120. The heater 130 may heat the substrate 10 to a predetermined temperature such that thin film deposition, stacking, and etching can be easily performed on the substrate 10. A coolant supply channel (not shown) may be provided in the susceptor 120 in order to supply a coolant to lower the temperature of the substrate 10.

The gas injector 140 is disposed in the chamber 110 at the upper side thereof to inject process gas or purge gas toward the substrate 10 seated on the susceptor 120. In the same manner as the susceptor 120, the gas injector 140 may be formed in a shape corresponding to the shape of the substrate 10. The gas injector 140 may be manufactured so as to have an approximately circular or quadrangular shape.

Meanwhile, as shown in FIG. 2, the substrate processing apparatus 100 according to the present inventive concept may further include a controller 180 and a calculator 190 disposed outside the chamber 110.

As shown in FIG. 1, the heater 130, which is disposed under the substrate to heat the substrate, and a first measurement unit 171 configured to measure the temperature of the heater 130 may be disposed in the chamber 110. A second measurement unit 172 may be disposed at the lead 100a, which is coupled to the upper end of the chamber body 110b.

The controller 180 and the calculator 190 may be disposed outside the chamber 110. The controller 180 performs control such that the first measurement unit 171 and the second measurement unit 172 measure the temperature of the heater 130 and the temperature of the substrate 10, respectively. The controller 180 may include a memory 181 configured to store temperature data measured by the first measurement unit 171 and the second measurement unit 172. This is an embodiment, and the memory 181 may be disposed outside the controller 180.

The calculator 190 may calculate the temperature of the substrate 10 using the measured temperature values of the heater 130 and the substrate 10 stored in the memory 181.

A plurality of second measurement units 172 may be disposed above the lead in order to measure the temperature of the substrate. The second measurement unit 172 may be constituted by an optical temperature sensor. As a representative example, a pyrometer may be used. The second measurement unit 172 may be disposed so as to measure the temperature of the substrate.

A plurality of first measurement units 171 may be disposed under the heater 130 to measure the temperatures of a plurality of areas of the heater.

In the embodiment of the present inventive concept, the number of the second measurement units 172 is different from the number of the first measurement units 171. Preferably, the number of the second measurement units 172 is less than the number of the first measurement units 171.

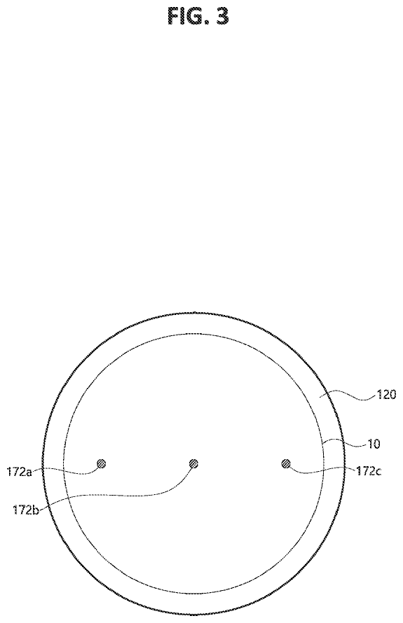

FIG. 3 is an illustrative view showing the area of the substrate measured by the second measurement unit in the substrate processing apparatus according to the construction of FIG. 1. That is, an embodiment applied to a process chamber using one substrate 10 disposed on the susceptor 120 is shown. At this time, the area of the substrate 10 measured by the plurality of second measurement units 172 may include a central part 172b of the substrate 10 and opposite area parts 172 and 172c of the substrate 10 located around the central part 172b in symmetry. A second measurement unit 172 according to a first embodiment may be disposed above the lead 110a.

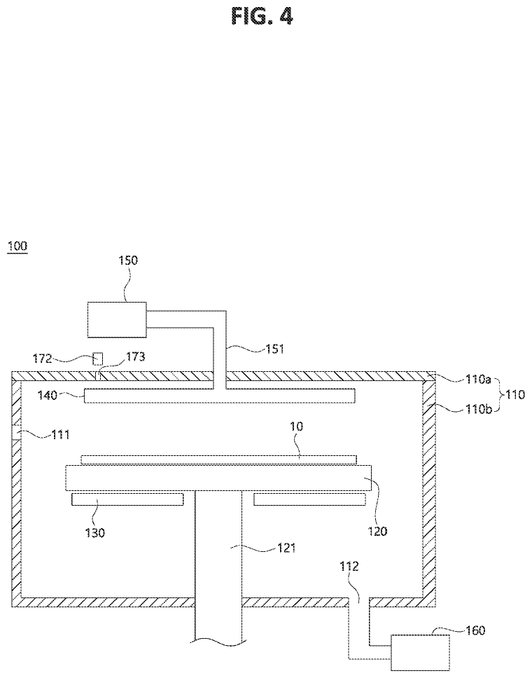

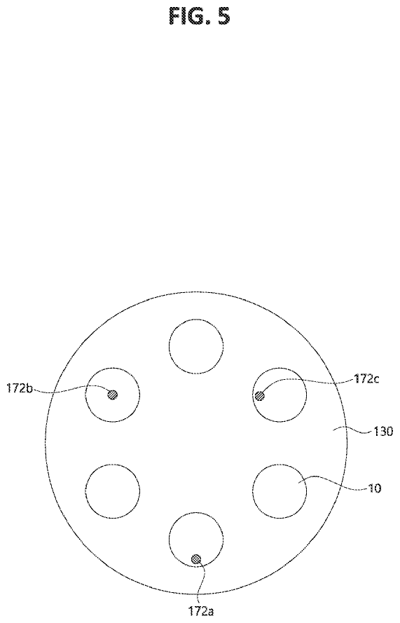

FIG. 4 is a view showing the internal construction of a chamber of a substrate processing apparatus according to another embodiment of the present inventive concept, and FIG. 5 is an illustrative view showing the area of a substrate measured by a second measurement unit in the substrate processing apparatus according to the construction of FIG. 4.

The other embodiment of the present inventive concept shows the case in which a plurality of substrates 10 is disposed on a susceptor 120 so as to be processed. At this time, second measurement units 172 may be disposed above different substrates. That is, three second measurement units 172 may be may be disposed above different substrates. In this embodiment, the second measurement units 172 may measure the temperatures of the plurality of substrates seated on the susceptor 120 through through-holes (not shown) formed in a gas injector 140, unlike an embodiment in which second measurement units are disposed in line at predetermined intervals to measure the temperatures of three areas of one substrate, as in the embodiment of FIG. 1. The second measurement units 172 may be disposed above different substrates 10 to measure the temperatures of the substrates located in different areas. For example, the second measurement units 172 may measure the temperatures of a plurality of areas 172a, 172b, and 172c. At this time, the controller 180 may perform control such that the second measurement units 172 are operated in synchronization with rotation cycles of the substrates 10 in order to measure the temperature of each area of the same substrate. That is, the controller 180 may provide operation approval signals to the second measurement units 172 such that second measurement units 172 are operated when the substrates again reach the positions at which the second measurement units 172 are disposed while being rotated. Meanwhile, the second measurement units 172 may be continuously operated to measure the temperatures of the substrates 10 and the susceptor 120 disposed thereunder. The temperature of the susceptor 120 is higher than the temperatures of the substrates 10. The reason for this is that heat is transmitted to the substrates 10 in the state in which the substrates 10 are disposed on the susceptor 120. A plurality of measured temperature values measured by the second measurement units 172 may be divided into measured temperature values of the substrates 10 and a measured temperature value of the susceptor 120. Thereamong, only the measured temperature values of the substrates 10 may be used.

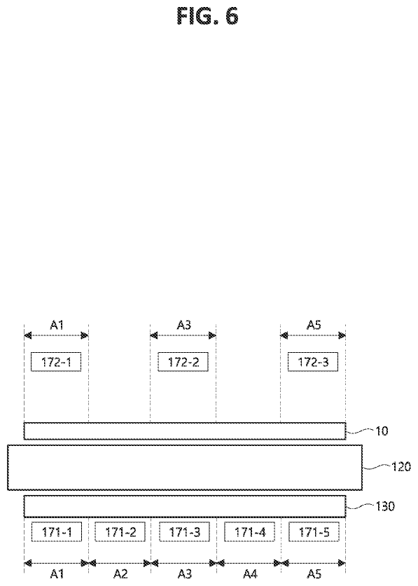

FIG. 6 is an illustrative view describing disposition and operation of the first measurement unit and the second measurement unit in the substrate processing apparatus according to the present inventive concept. Hereinafter, an embodiment in which one substrate 10 is seated on the susceptor 120 will be described in order to assist in understanding of the inventive concept; however, the operation thereof is similar to the operation in the case in which a plurality of substrates 10 is seated on the susceptor 120.

In this embodiment, as shown in FIG. 6, the first measurement unit 171 configured to measure the temperature of the heater 130 includes five sensors 171-1, 171-2, 171-3, 171-4, and 171-5, and the second measurement unit 172 configured to measure the temperature of the substrate 10 includes three sensors 172-1, 172-2, and 172-3. However, the present inventive concept is not limited thereto, as mentioned above. That is, it does not matter as long as the condition in which the number of temperature sensors constituting the first measurement unit and the number of temperature sensors constituting the second measurement unit are different from each other is satisfied. It is preferable for the number of temperature sensors constituting the second measurement unit to be relatively small, as in this embodiment.

The first measurement unit 171 is disposed under the heater 130 to measure the temperatures of five areas A1 to A5 of the heater 130, and the second measurement unit 172 is disposed above the substrate 10 to measure three areas A1, A3, and A5 of the substrate 10.

The 1-1 measurement unit 171-1 constituting the first measurement unit 171 may measure the temperature of the area A1 of the heater 130, the 1-2 measurement unit 171-2 may measure the temperature of the area A2 of the heater 130, the 1-3 measurement unit 171-3 may measure the temperature of the area A3 of the heater 130, the 1-4 measurement unit 171-4 may measure the temperature of the area A4 of the heater 130, and the 1-5 measurement unit 171-5 may measure the temperature of the area A5 of the heater 130. Meanwhile, the 2-1 measurement unit 172-1 constituting the second measurement unit 172 above the substrate 10 may measure the temperature of the area A1 of the substrate 10, the 2-2 measurement unit 172-2 may measure the temperature of the area A3 of the substrate 10, and the 2-3 measurement unit 172-3 may measure the temperature of the area A5 of the substrate 10.

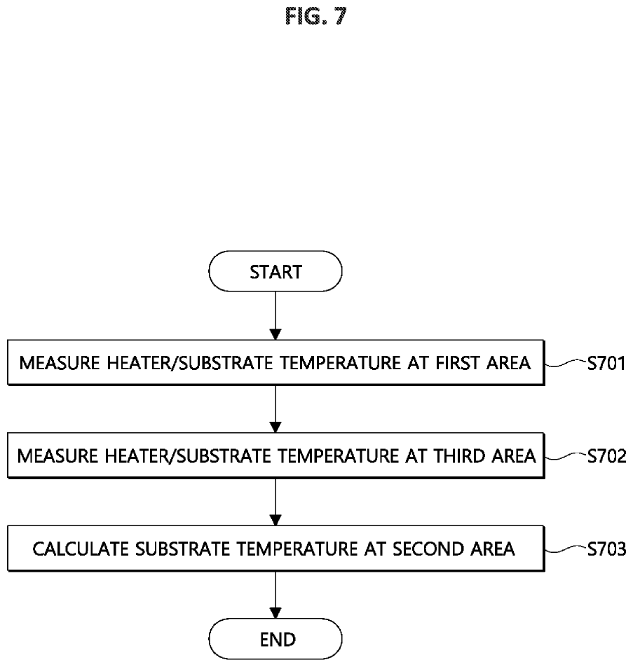

FIG. 7 is a flowchart showing steps of a substrate processing method according to the present inventive concept. When a process is performed and the temperature in the chamber reaches a predetermined temperature, whereby the chamber is stabilized, the controller 180 may perform control such that the first measurement unit 171 and the second measurement unit 172 measure the temperatures of the heater 130 and the substrate 10, respectively.

In the following description, “first area” may indicate “area A1 or area A3”, “third area” may indicate “area A3 or area A5”, and “second area” may indicate “area A2 or area A4”. That is, in the “second area”, which is an area between the “first area” and the “third area”, the first measurement unit 171 is disposed under the heater 130 but the second measurement unit 172 is not disposed above the substrate 10. On the assumption that “area A1” is “first area” and “area A3” is “third area” in the illustrative view of FIG. 6, therefore, “second area” may indicate “area A2”. On the assumption that “area A3” is “first area” and “area A5” is “third area”, “second area” may be “area A4”.

In the following description, “area A1” will be referred to as “first area”, “area A3” will be referred to as “third area”, and “area A2” will be referred to as “second area”.

Under control of the controller 180, the 1-1 measurement unit 171-1 and the 2-1 measurement unit 172-1 measure the temperature of the first area of the heater and the temperature of the first area of the substrate, respectively (S701).

The 1-3 measurement unit 171-3 and the 2-2 measurement unit 172-2 may measure the temperature of the third area of the heater and the temperature of the third area of the substrate, respectively. The measured temperature values of the heater and the substrate measured by the respective measurement units 171-1, 171-3, 172-1, and 172-2 are stored in the memory 181. Meanwhile, in the above description, the temperatures of the first area and the third area of the heater and the substrate are sequentially measured in order to assist in understanding of the inventive concept; however, temperature measurements may be simultaneously performed (S702).

The calculator 190 may calculate the temperature of the second area of the substrate using the values stored in the memory 181. That is, the calculator 190 may calculate the temperature of the second area, which is between the first area and the third area, of the substrate using the measured temperature values of the first areas of the substrate and the heater and the measured temperature values of the third areas of the substrate and the heater. The calculator 190 may use at least one of the difference between the measured values of the first areas measured by the first measurement unit and the second measurement unit and the measured values of the third areas measured by the first measurement unit and the second measurement unit and the average thereof.

First, a method of calculating the average of the temperature value of the first area of the substrate measured by the 2-1 measurement unit 172-1 and the temperature value of the second area of the substrate measured by the 2-2 measurement unit 172-2 as the temperature value of the second area, which is between the first area and the third area, of the substrate may be simply used. However, the measured temperature value of the second area of the heater is not reflected in this value, and therefore an error range is large.

As another method, the case in which the calculator 190 uses the difference (offset) between the measured values of the first area and the third area will be described. At this time, the measured value of the second area of the heater measured by the first measurement unit may be further used. For example, on the assumption that the temperatures of the first area and the third area of the substrate are TA1S and TA3S and the temperatures of the first area and the third area of the heater are TA1H and TA3H, the temperature differences between the substrate and the heater at the first area and the third area may be calculated as ΔA1 and ΔA3, respectively. At this time, on the assumption that the average of ΔA1 and ΔA3 is ΔA2, the temperature of the second area of the substrate may be calculated by subtracting ΔA2, which is the average of ΔA1 and ΔA3, from the value of the second area measured by the 1-2 measurement unit 171-2.

The temperature of the substrate at the area A4 at which the second measurement unit is not disposed may be measured using the above method (S703).

When the temperatures of the first to third areas of the substrate have a difference within an error range, compared to the temperatures of the other areas of the substrate, it is possible to control the heater under the areas such that the temperature of the substrate is uniform. If the temperatures of certain areas of the substrate have a difference out of the error range, it may be determined that the heater or the measurement unit disposed under the areas is abnormal, and an alarm may be provided to a user.

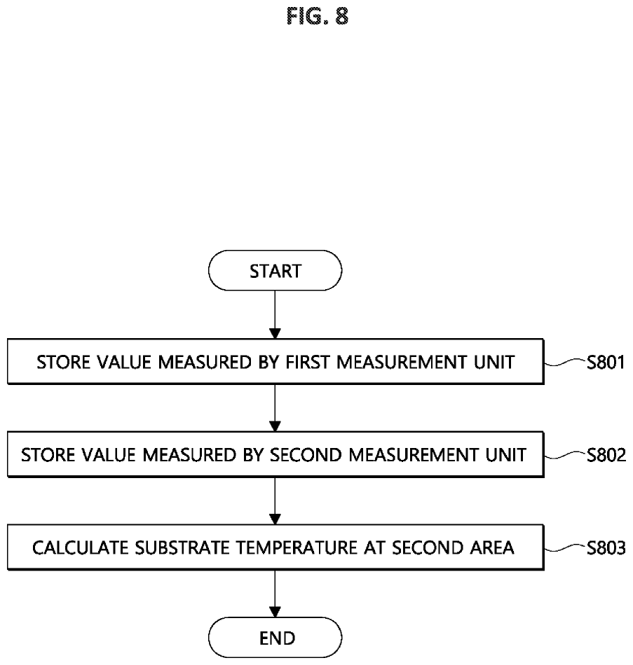

Meanwhile, in a substrate processing method according to another embodiment of the present inventive concept shown in FIG. 8, the temperature of the heater may be measured using the first measurement unit and stored in a pre-processing step of setting up the substrate processing apparatus before a process, and the temperature of the substrate may be measured during the process, whereby the temperature of the second area of the substrate may be measured.

In the pre-processing step, i.e. a first step, the temperatures of the heater are measured using the first measurement units 171-1, 171-2, 171-3, 171-4, and 171-5, and are stored in the memory 181. In an initial set-up step of process equipment, the measured temperature values of the five areas of the heater measured using a first measurement unit constituted by a plurality of thermocouples are stored in advance (S801).

During the process, the temperatures of the areas A1, A3, and A5 of the substrate are measured using the second measurement unit 172 and are stored in the memory 181 (S802).

The controller 180 may calculate the temperature value of the second area of the substrate using the measured temperature values of the first areas of the heater and the substrate and the measured temperature values of the third areas of the heater and the substrate stored in the memory. At this time, the operation of the controller 180 is identical to the operation of the controller described in step S704 of FIG. 7.

In the substrate processing apparatus and method according to the present inventive concept, as described above, even though the second measurement units are not disposed at the positions of the first measurement units disposed under the heater, it is possible to calculate the temperatures of the areas of the substrate and to monitor the temperature of the substrate in real time based thereon in order to control the temperature of the heater, whereby it is possible to maintain uniform temperature of the entirety of the substrate. As a result, it is possible to deposit a film having a uniform thickness, thereby improving completeness of a deposition process.

As is apparent from the above description, in a substrate processing apparatus and method according to the present inventive concept, it is possible to measure the temperature of a substrate in a chamber in real time and to control the temperature of a heater using the measured temperature data of the substrate, whereby it is possible to improve temperature uniformity of the substrate, and therefore it is possible to improve completeness of a deposition process.

Effects obtainable from the present inventive concept are not limited by the above mentioned effects, and other unmentioned effects can be clearly understood from the above description by those having ordinary skill in the technical field to which the present inventive concept pertains.

Although the preferred embodiments of the present inventive concept have been described above with reference to the accompanying drawings, those skilled in the art will appreciate that various modifications and alterations are possible without departing from the idea and field of the present inventive concept set forth in the appended claims.

1. A substrate processing apparatus comprising:
a chamber;
a susceptor configured to support a substrate in the chamber;
a heater disposed under the susceptor;
one or more first measurement units configured to measure temperature of the heater; and
one or more second measurement units configured to measure temperature of the substrate,
wherein the first measurement units and the second measurement units are different from each other in number.

2. The substrate processing apparatus according to claim 1, wherein the number of the second measurement units is less than the number of the first measurement units.

3. The substrate processing apparatus according to claim 1, wherein the second measurement units are spaced apart from each other by a predetermined distance.

4. The substrate processing apparatus according to claim 1, further comprising a calculator configured to calculate temperature of a second area of the substrate using measured values of a first area measured by the first measurement unit and the second measurement unit and measured values of a third area measured by the first measurement unit and the second measurement unit, the second area being located between the first area and the third area.

5. The substrate processing apparatus according to claim 4, wherein the calculator calculates the temperature of the second area of the substrate using at least one of a difference between the measured values of the first area measured by the first measurement unit and the second measurement unit and the measured values of the third area measured by the first measurement unit and the second measurement unit and an average thereof.

6. The substrate processing apparatus according to claim 5, wherein the calculator calculates the temperature of the second area of the substrate further using a measured value of the second area measured by the first measurement unit.

7. The substrate processing apparatus according to claim 1, wherein
the susceptor is rotatable while supporting a plurality of substrates, and
the second measurement units are disposed above the plurality of substrates, respectively.

8. A substrate processing method comprising:
a first step of measuring heater temperature and substrate temperature at a first area;
a second step of measuring heater temperature and substrate temperature at a third area; and
a third step of calculating substrate temperature at a second area using the measured values of the first area and the second area, the second area being located between the first area and the third area.

9. The substrate processing method according to claim 8, wherein the substrate temperature at the second area is calculated using at least one of a difference between the heater temperature and the substrate temperature at the first area and the third area and an average thereof.

10. The substrate processing method according to claim 8, further comprising a step of measuring heater temperature at the second area to calculate the substrate temperature at the second area.

11. A substrate processing method comprising:
a first step of measuring and storing heater temperature;
a second step of measuring and storing substrate temperature; and
a third step of calculating substrate temperature at a second area using a measured heater temperature value and a measured substrate temperature value at a first area and a measured heater temperature value and a measured substrate temperature value at a third area, the second area being located between the first area and the third area.

12. The substrate processing method according to claim 11, wherein the substrate temperature at the second area is calculated using at least one of a difference between the heater temperature and the substrate temperature at the first area and the third area and an average thereof.

13. The substrate processing method according to claim 11, wherein the substrate temperature at the second area is calculated further using a measured heater temperature value at the second area.
